(19) United States
(12) Patent Application Publication
(10) Pub. No.: US 2026/0314291 A1
(43) Pub. Date: Oct. 8, 2026

(54) METHOD FOR CONTROLLING DUMMY GATE PROFILE

(71) Applicant: Tokyo Electron Limited, Tokyo (JP)

(72) Inventor: Minjoon Park, Albany, NY (US)

(21) Appl. No.: 19/465,586

(22) Filed: Jan. 30, 2026

Related U.S. Application Data
(60) Provisional application No. 63/784,327, filed on Apr. 7, 2025.

(51) Int. Cl. H10P 70/00; H10D 64/01

(52) U.S. Cl. CPC H10P 70/27; H10D 64/017

(57) ABSTRACT

A method includes providing a substrate having a fin formed thereon, forming a dummy gate dielectric layer along sidewalls and a top surface of the fin, forming a dummy gate electrode layer over the dummy gate dielectric layer, and patterning the dummy gate electrode layer to form a dummy gate. A sidewall of the dummy gate includes a first residue. The method further includes amorphizing the first residue to form an amorphized first residue and selectively removing the amorphized first residue.

### CROSS-REFERENCE TO RELATED APPLICATIONS

This application claims the benefit of U.S. Provisional Application No. 63/784,327, filed on April 7, 2025, which application is hereby incorporated herein by reference.

### TECHNICAL FIELD

The present disclosure relates generally to methods of processing a substrate, and, in particular embodiments, to a method for controlling a dummy gate profile.

### BACKGROUND

Modern semiconductor manufacturing involves the fabrication of complex three-dimensional device structures such as fin field-effect transistors (FinFETs) and gate-all-around (GAA) transistors to meet the demands of advanced technology nodes. These structures typically include vertical elements such as fins or nanowires that extend from substrates, with various layers and materials deposited to form functional electronic devices. The manufacturing process involves multiple steps including material deposition, lithography, etching, and thermal processing to create the desired device architectures.

### SUMMARY

In accordance with an embodiment, a method includes providing a substrate having a fin formed thereon; forming a dummy gate dielectric layer along sidewalls and a top surface of the fin; forming a dummy gate electrode layer over the dummy gate dielectric layer; patterning the dummy gate electrode layer to form a dummy gate, a sidewall of the dummy gate including a first residue; amorphizing the first residue to form an amorphized first residue; and selectively removing the amorphized first residue.

In accordance with another embodiment, a method includes providing a substrate having a fin extending from a major surface of the substrate; forming a dummy gate dielectric layer along sidewalls and a top surface of the fin; forming a dummy gate electrode layer over the dummy gate dielectric layer; patterning the dummy gate electrode layer to form one or more trenches in the dummy gate electrode layer, where the one or more trenches include one or more residues; performing a particle treatment on the one or more residues to form amorphized one or more residues; and selectively removing the amorphized one or more residues.

In accordance with yet another embodiment, a method includes providing a substrate having a fin formed thereon; depositing a dielectric layer along sidewalls and a top surface of the fin; depositing a polysilicon layer over the dielectric layer; etching the polysilicon layer to form a dummy gate, a sidewall of the dummy gate including a first residue and a sidewall of the fin including a second residue; performing a particle treatment on the first residue and the second residue to form a modified first residue and a modified second residue, where the modified first residue and the modified second residue include amorphous silicon; and selectively etching the modified first residue and the modified second residue.

### BRIEF DESCRIPTION OF THE DRAWINGS

For a more complete understanding of the present disclosure, and the advantages thereof, reference is now made to the following descriptions taken in conjunction with the accompanying drawings, in which:

FIGS. 1A-9A, 1B-9B, and 5C-9C illustrate top and cross-sectional views of intermediate stages in the manufacturing of a semiconductor device, in accordance with various embodiments; and

FIG. 10 illustrates a flow diagram of a method for controlling a dummy gate profile, in accordance with various embodiments.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

While various embodiments of the present disclosure are described primarily in the context of fin field-effect transistor (FinFET) devices with fin structures, it should also be appreciated that various embodiments may also apply to gate-all-around (GAA) transistors, nanowire devices, and nanosheet transistors. In particular, various embodiments of the present disclosure may similarly apply to any three-dimensional semiconductor device structure where gate electrodes are formed adjacent to or around vertical semiconductor elements, including vertical transistors, stacked nanosheet devices, and other device architectures where enhanced control of gate profiles at interfaces with semiconductor structures is beneficial.

Semiconductor fabrication processes for three-dimensional transistor structures, such as FinFETs, face challenges related to residual material remaining after gate patterning operations. During gate electrode layer patterning, residual crystalline silicon material may remain along sidewalls of gate structures and fin structures, particularly at locations where different planes intersect. These residues, commonly referred to as stringers and skirts, can cause device failures and performance degradation. Stringers extending between adjacent gate structures can create electrical short circuits between transistors. Skirts extending along gate sidewalls can cause threshold voltage shifts due to variations in gate dimensions and geometry. As device dimensions continue to shrink, these residues become increasingly problematic, potentially causing failures even when not clearly visible through conventional imaging techniques.

Embodiments of the present disclosure address these challenges through a multi-step residue removal process that combines physical modification and selective removal. Following the gate patterning process, a particle treatment is performed to convert residual crystalline silicon into amorphous silicon. The particle treatment may include a gas cluster beam treatment, an ion beam treatment, or a plasma treatment using inert or non-reactive species. The particle treatment employs directional beams, typically oriented vertically or at slight angles relative to the substrate surface, to selectively target exposed residues while leaving protected structures intact. A gate mask positioned over the gate structure shields the underlying gate electrode from the particle treatment. An oxide layer positioned over the fin structure similarly protects the fin from the particle treatment. The beam energy and ion species are selected based on the material composition and desired amorphization depth.

Following the amorphization process, a selective wet etch process is performed to remove the amorphized silicon. The wet etch process may utilize alkaline solutions such as potassium hydroxide (KOH) or sodium hydroxide (NaOH), which exhibit higher etch rates for amorphous silicon compared to crystalline silicon. This selectivity enables removal of the amorphized residues while preserving crystalline silicon structures, including the gate electrode and fin structures. The etch rate differential between amorphous and crystalline silicon provides a process window for complete residue removal without damaging functional device structures.

Embodiments of the present disclosure provide several advantages over conventional approaches. The two-step amorphization and selective removal process enables elimination of stringers and skirts without requiring excessive over-etching during the initial gate patterning step. This preserves gate profile integrity and prevents damage to gate dielectric layers that can occur with aggressive over-etching. The selective nature of the wet etch process reduces or minimizes unintended removal of crystalline silicon from gate electrodes and fin structures. The process can be integrated into existing replacement gate fabrication flows, where dummy gate structures are subsequently replaced with final gate structures. The method addresses scaling challenges associated with continued device miniaturization, where conventional over-etch approaches become increasingly difficult to control.

In various embodiments, the particle treatment parameters, including beam energy, ion species, treatment duration, and beam angle, can be adjusted based on the amount and location of residual material. For residues located at corners where two planes intersect, vertical beam orientation may provide sufficient coverage. For residues extending along sidewalls, slightly tilted beams may enhance treatment uniformity. The treatment duration can be determined through empirical testing to identify process conditions that achieve complete amorphization of residues while reducing or minimizing exposure of protected structures. The wet etch process parameters, including solution concentration, temperature, and etch duration, can similarly be tuned to achieve complete residue removal while maintaining selectivity to crystalline silicon.

The disclosed embodiments can be applied to various three-dimensional transistor architectures beyond FinFETs, including nanosheet transistors, nanowire transistors, gate-all- around transistors, and three-dimensional memory structures. The disclosed methods can be performed using commercially available semiconductor processing equipment, including dry etch tools for gate patterning, particle beam tools for amorphization, and wet etch tools for selective removal.

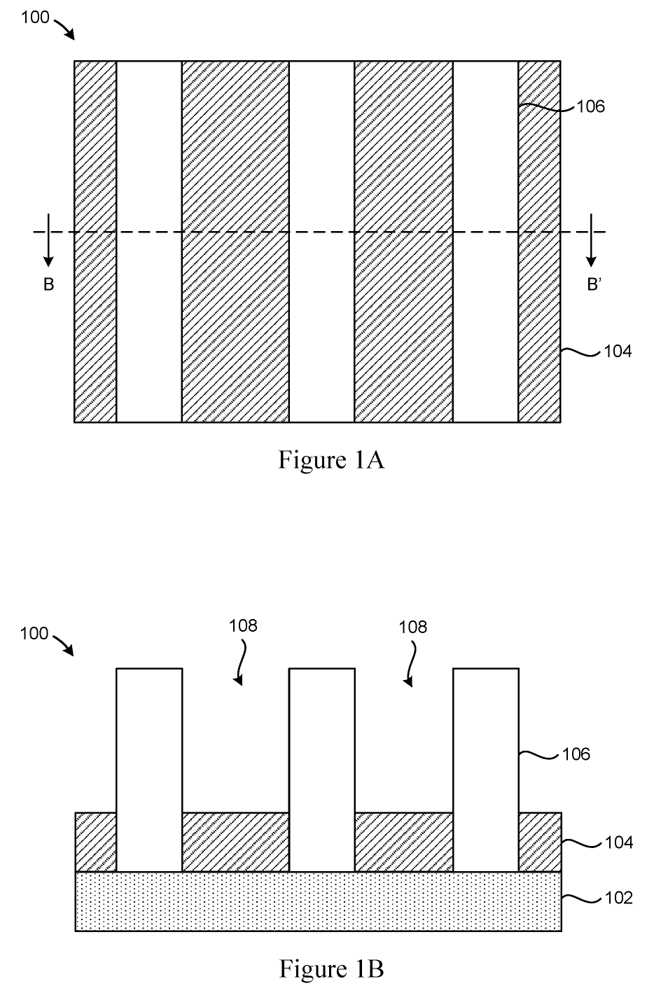

FIGS. 1A-9A, 1B-9B, and 5C-9C illustrate top and cross-sectional views of intermediate stages in the manufacturing of a semiconductor device 100, in accordance with various embodiments. In particular, “A” figures illustrate top views, “B” figures illustrate cross-sectional views along BB’ lines in respective “A” figures, and “C” figures illustrate cross-sectional views along CC’ lines in respective “A” figures.

FIGS. 1A and 1B illustrate an initial stage in the formation of a semiconductor device 100, showing a substrate 102 with fins 106 formed thereon. The substrate 102 serves as the base material for the semiconductor device 100 and may comprise various semiconductor materials depending on the specific application requirements. In various embodiments, the substrate 102 comprises silicon, silicon-germanium, gallium arsenide, indium gallium arsenide, or other III-V compound semiconductors. The substrate 102 may also comprise silicon-on-insulator (SOI) structures with a buried oxide layer, germanium-on-insulator substrates, or other engineered substrate configurations.

The isolation regions 104 define and separate individual fins 106, providing electrical isolation between adjacent device regions. The isolation regions 104 may comprise shallow trench isolation (STI) structures filled with dielectric materials such as silicon dioxide, silicon nitride, silicon oxynitride, high-k dielectric materials, a combination thereof, or the like. In various embodiments, the isolation regions 104 are formed by etching trenches in the substrate 102 using anisotropic dry etching techniques such as reactive ion etching (RIE) or deep reactive ion etching (DRIE). The trenches may be filled with dielectric material using chemical vapor deposition (CVD), atomic layer deposition (ALD), spin-on deposition, a combination thereof, or the like. In an embodiment, the dielectric fill material may be planarized using chemical mechanical polishing (CMP) to achieve a planar surface.

The fins 106 extend vertically from the substrate 102 and define the active device regions where transistor channels will be formed. Each fin 106 has sidewalls and a top surface that provide multiple surfaces for gate control in three-dimensional device architectures. In an embodiment, the fins 106 may be formed through various lithography and etching techniques. In various embodiments, the fins 106 are defined using hard mask materials such as silicon nitride, silicon dioxide, or amorphous carbon, followed by anisotropic etching to transfer the pattern into the substrate 102. In some embodiments, the fins 106 and the substrate 102 comprise a same semiconductor material. In other embodiments, the fins 106 and the substrate 102 comprise different semiconductor materials.

The trenches 108 are formed between adjacent fins 106. The trenches 108 provide access for subsequent deposition and processing steps, allowing conformal coating of materials around the fins 106. In an embodiment, the trenches 108 may be formed through etching steps that recesses top surfaces of the isolation regions 104 below top surfaces of the fins 106.

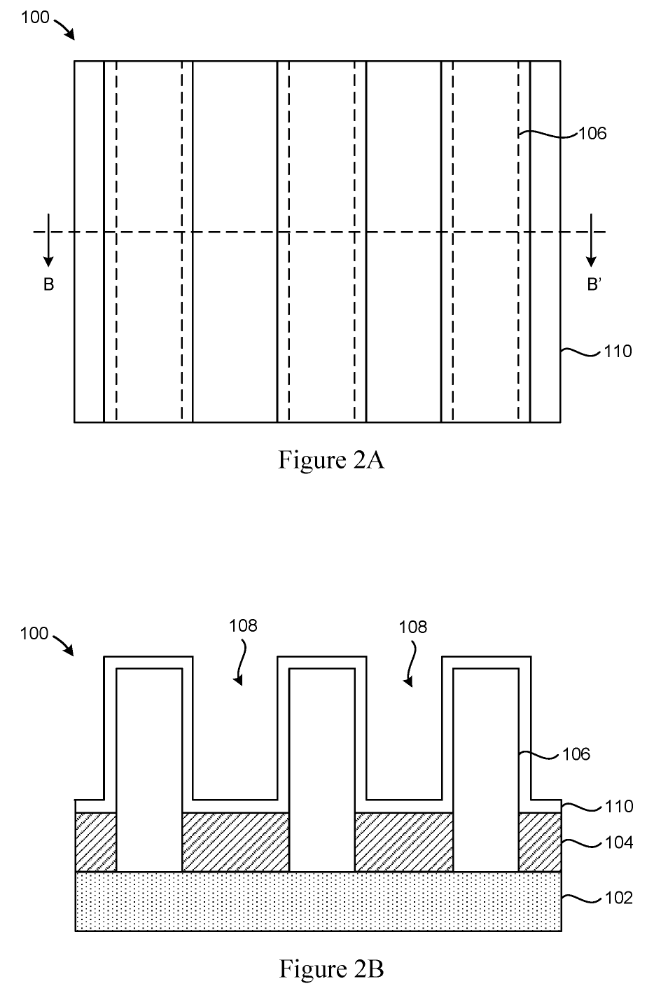

In FIGS. 2A and 2B, a dielectric layer 110 is formed over the fins 106 and isolation regions 104. In some embodiments, the dielectric layer 110 provides a conformal coating covering the sidewalls and top surfaces of the fins 106 as well as the exposed surfaces of the isolation regions 104. In some embodiments, the dielectric layer 110 may be a temporary layer that is fully or partially removed in subsequent process steps. In such embodiments, the dielectric layer 110 may be also referred to as a dummy dielectric layer or a dummy gate dielectric layer.

In an embodiment, the dielectric layer 110 may comprise silicon dioxide formed through thermal oxidation of the fins 106 in an oxygen-containing ambient. The thermal oxidation process may be performed in dry oxygen, wet oxygen, or steam environments to achieve different oxidation rates and oxide quality characteristics. In an embodiment, the dielectric layer 110 may comprise silicon oxynitride formed through nitridation of silicon dioxide using nitrogen-containing plasmas or thermal nitridation processes. In some embodiments, materials for the dielectric layer 110 include high-k dielectric materials such as hafnium oxide, aluminum oxide, zirconium oxide, tantalum oxide, lanthanum oxide, or the like.

In various embodiments, the dielectric layer 110 may be formed using deposition techniques rather than thermal growth processes. The deposition techniques such as CVD techniques, including low-pressure CVD (LPCVD), plasma-enhanced CVD (PECVD), or ALD, can be employed to deposit the dielectric layer 110.

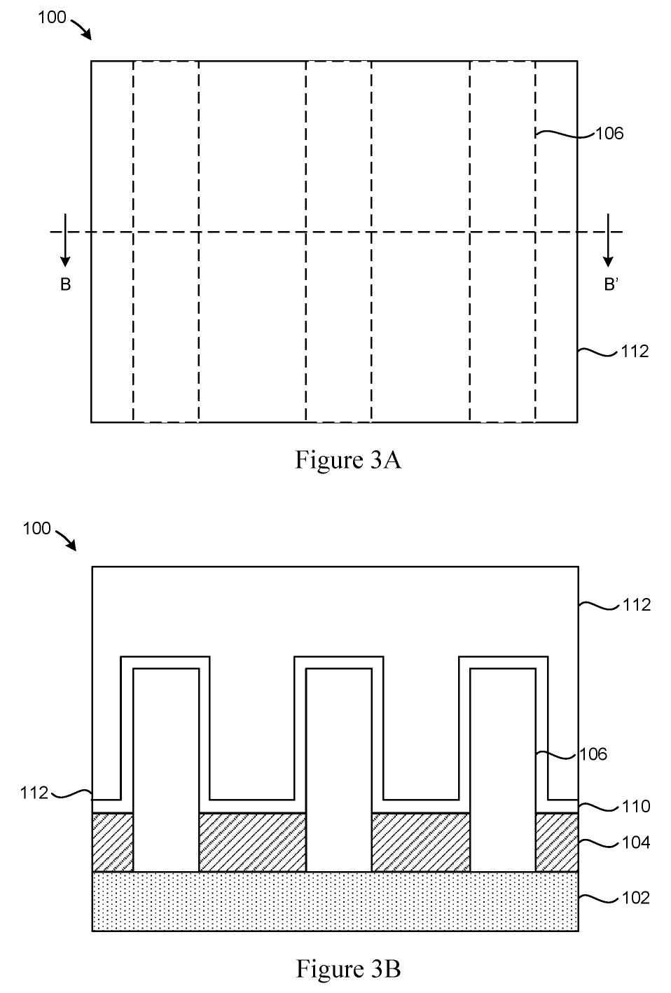

In FIGS. 3A and 3B, a dummy gate electrode layer 112 is formed over the dielectric layer 110. In some embodiments, the dummy gate electrode layer 112 may overfill the trenches 108 (see FIG. 3B) between the fins 106 and extend above the top surfaces of the fins 106. As described below in greater detail, the dummy gate electrode layer 112 may serve as a placeholder material that will later be replaced with a metal gate electrode in a replacement gate process flow.

The dummy gate electrode layer 112 may comprise a semiconductor material that can be selectively removed during subsequent replacement gate processes. In various embodiments, the dummy gate electrode layer 112 may comprise polycrystalline silicon (polysilicon), polycrystalline germanium, silicon-germanium alloys, a combination thereof, or the like, and may be deposited using CVD, LPCVD, PECVD, ALD, a combination thereof, or the like. The polysilicon deposition may employ silane (SiH₄), disilane (Si₂H₆), or dichlorosilane (SiH₂Cl₂) as silicon precursors in a CVD process, for example.

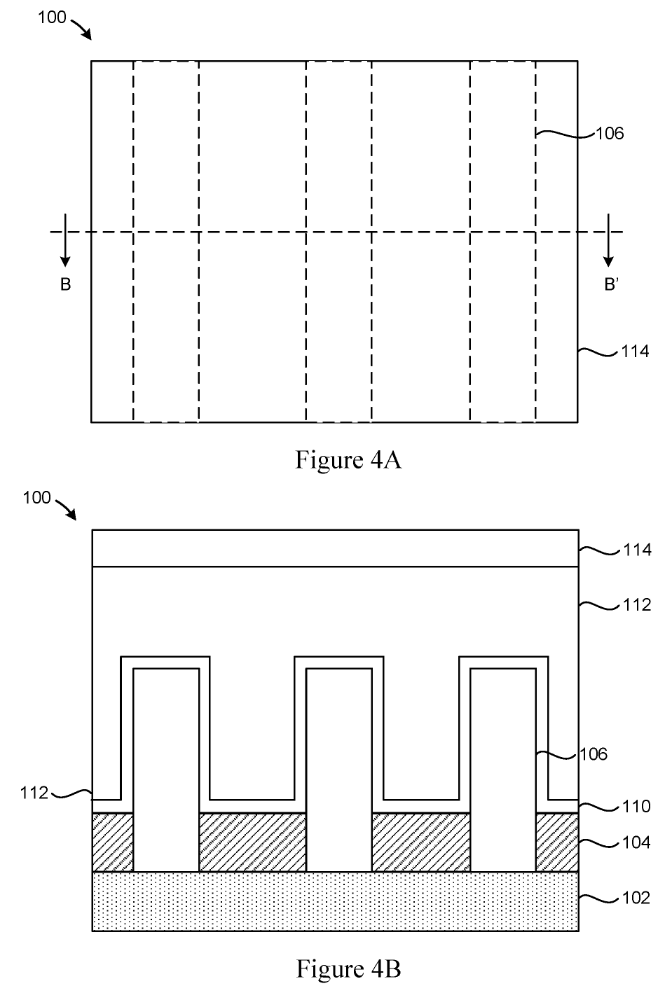

In FIGS. 4A and 4B, a mask layer 114 is formed over the dummy gate electrode layer 112. In some embodiments, the mask layer 114 serves as a hard mask that provides etch selectivity and pattern transfer capability for defining gate dimensions and profiles. The mask layer 114 comprises a material that provides high etch selectivity relative to the underlying dummy gate electrode layer 112. In various embodiments, the mask layer 114 may comprise silicon dioxide, silicon nitride, titanium nitride, aluminum oxide, amorphous carbon, a combination thereof, or the like, and may be formed using CVD, LPCVD, PECVD, ALD, a combination thereof, or the like.

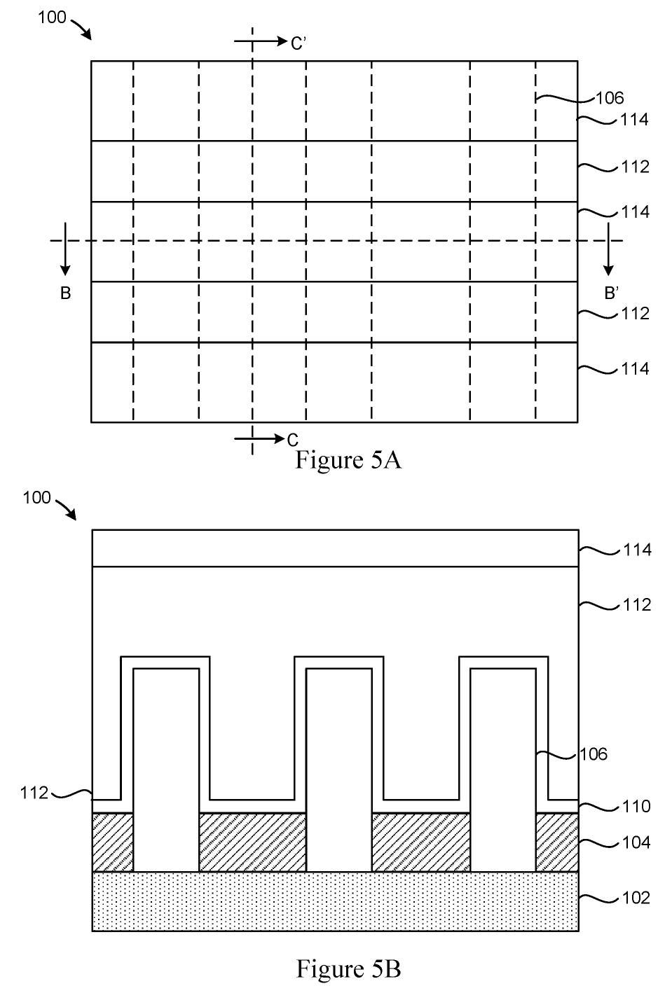

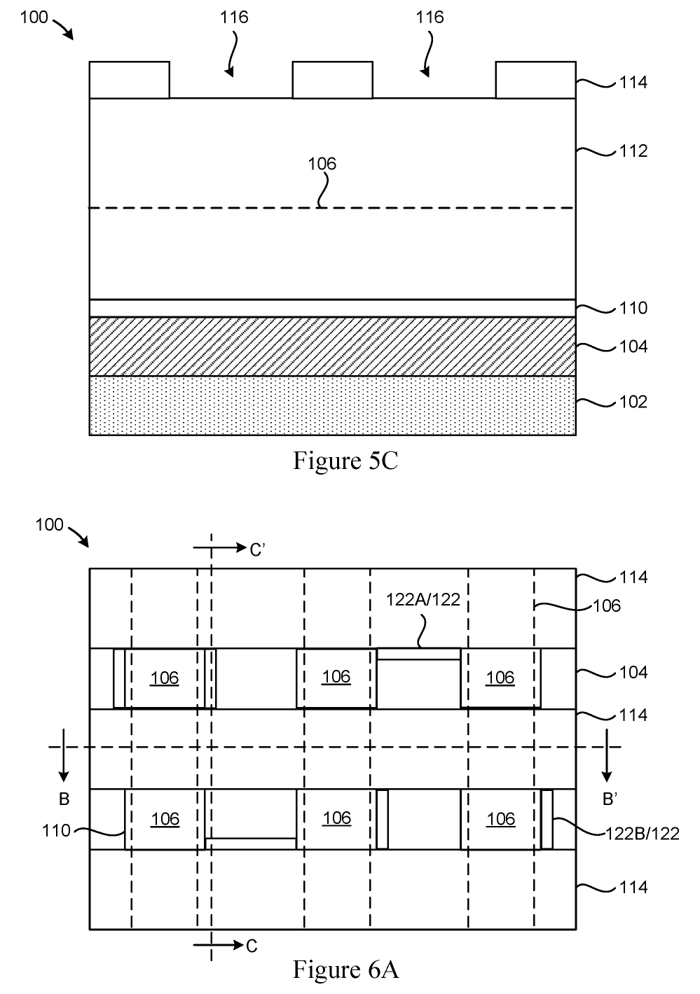

In FIGS. 5A, 5B, and 5C, the mask layer 114 is patterned to define gate regions. The patterned mask layer 114 comprises elongated regions that extend across multiple fins 106 and are separated by openings 116. The elongated regions define the locations of gate structures that extend across multiple fins 106 and control multiple fin channels simultaneously. In some embodiments, the patterning process may comprise suitable photolithography and etch processes. The etch processes may comprise suitable wet or dry etch processes. In an embodiment, the etch processes comprise an anisotropic dry etch process such as a RIE process. In some embodiments, the etch processes may be plasma-assisted or plasma-free processes.

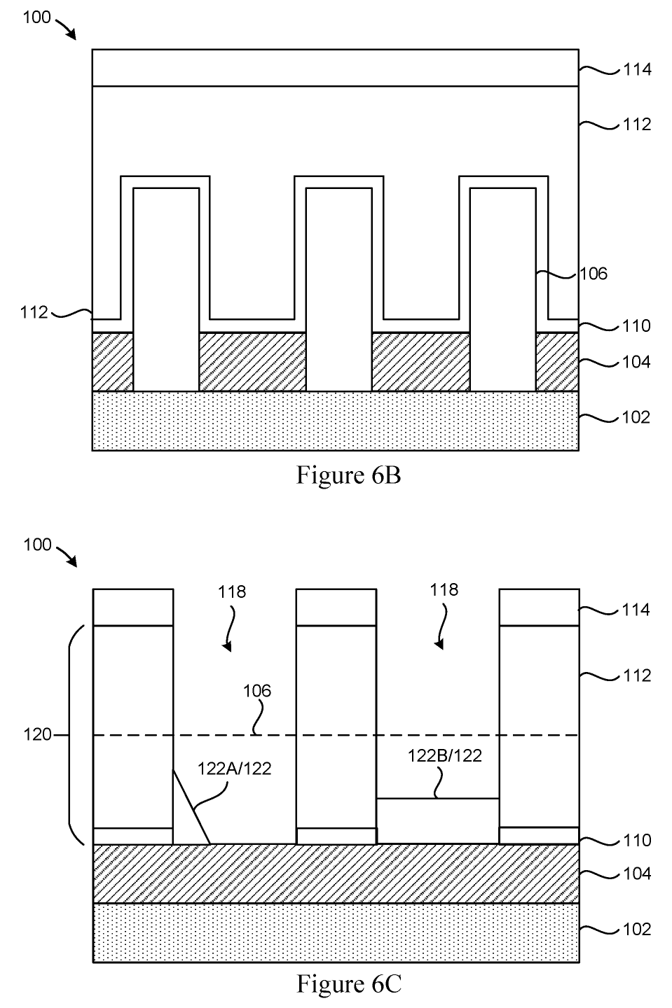

In FIGS. 6A, 6B, and 6C, a patterning process forms dummy gate stacks 120 by etching the dummy gate electrode layer 112 and the dielectric layer 110. Each dummy gate stack 120 includes a patterned dielectric layer 110 positioned along sidewalls and top surfaces of the fins 106, and a patterned dummy gate electrode layer 112 positioned over the dielectric layer 110. The mask layer 114 remains positioned over the dummy gate electrode layer 112 following the patterning process. The patterning process creates trenches 118 between adjacent dummy gate stacks 120, exposing portions of the fins 106 and the isolation regions 104 within the trenches 118.

The patterning process may include one or more dry etch processes configured to remove material from the dummy gate electrode layer 112 and the dummy gate dielectric layer 11- in regions not protected by the mask layer 114. In an embodiment, the dry etch process includes a plasma-based etch (e.g., RIE) using etch chemistries selected for silicon removal. The etch process is performed with parameters configured to achieve anisotropic etching, creating substantially vertical sidewalls on the dummy gate stacks 120. In various embodiments, the etch process includes multiple steps with different etch chemistries to sequentially remove the dummy gate electrode layer 112 and the dielectric layer 110.

In some embodiments, the patterning process results in residues 122 (including residues 122A and 122B) remaining along sidewalls of the dummy gate stacks 120 and sidewalls of the fins 106. The residues 122A, commonly referred to as skirts, extend along sidewalls of the dummy gate stacks 120 within the trenches 118 separating adjacent dummy gate stacks 120. The residues 122B, commonly referred to as stringers, extend along sidewalls of the fins 106 within the trenches 118. The residues 122 (including residues 122A and 122B) comprise crystalline silicon material that was not completely removed during the patterning process. In various embodiments, the residues 122 (including residues 122A and 122B) form at locations where two planes intersect, such as corners where the dummy gate electrode layer 112 meets the isolation regions 104, corners where the fins 106 meet the isolation regions 104, or corners where the dummy gate electrode layer 112 meets the fins 106.

The residues 122A can affect the performance of subsequently formed transistors by altering the effective gate dimensions and geometry. Variations in gate dimensions can cause threshold voltage shifts and other performance variations. The residues 122B can create electrical connections between adjacent transistor structures. If the residues 122B extend between adjacent dummy gate stacks 120, they can cause short circuits between transistors, leading to device failure. As device dimensions continue to shrink, even small amounts of residual material can cause significant performance degradation or failures.

As shown in FIG. 6A, the dielectric layer 110 remains positioned over the top surfaces and sidewalls of the fins 106 following the patterning process. The dielectric layer 110 protects the underlying fin material during the patterning process and subsequent processing steps. The dummy gate stacks 120 extend across multiple fins 106, forming gate structures that will control current flow through channel regions of the fins 106 in the completed transistor devices.

In various embodiments, the amount of residual material in the residues 122 (including residues 122A and 122B) may be relatively small and may not be clearly visible through conventional imaging techniques such as scanning electron microscopy or transmission electron microscopy. Despite the small amount of residual material, the residues 122 (including residues 122A and 122B) can cause device failures, particularly as device dimensions continue to shrink. Conventional approaches to eliminate these residues include increasing the over-etch time during the patterning process. However, excessive over-etching can degrade the profile of the dummy gate stacks 120, consume the mask layer 114, or damage the dielectric layer 110. As described below in greater detail, these challenges may be addressed through subsequent amorphization and selective removal processes.

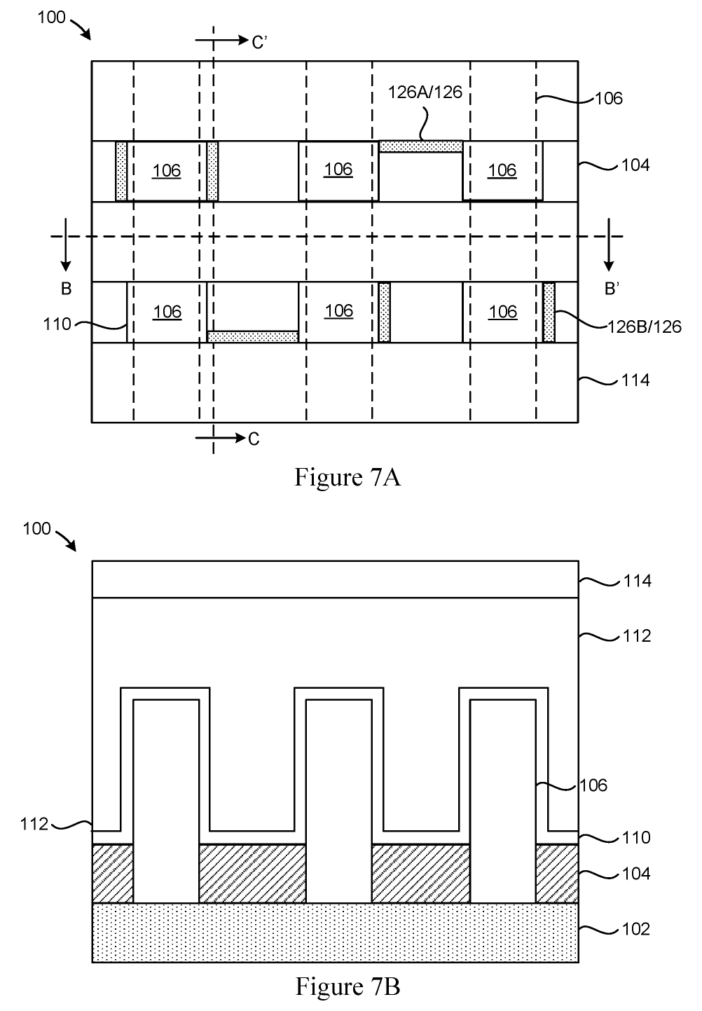

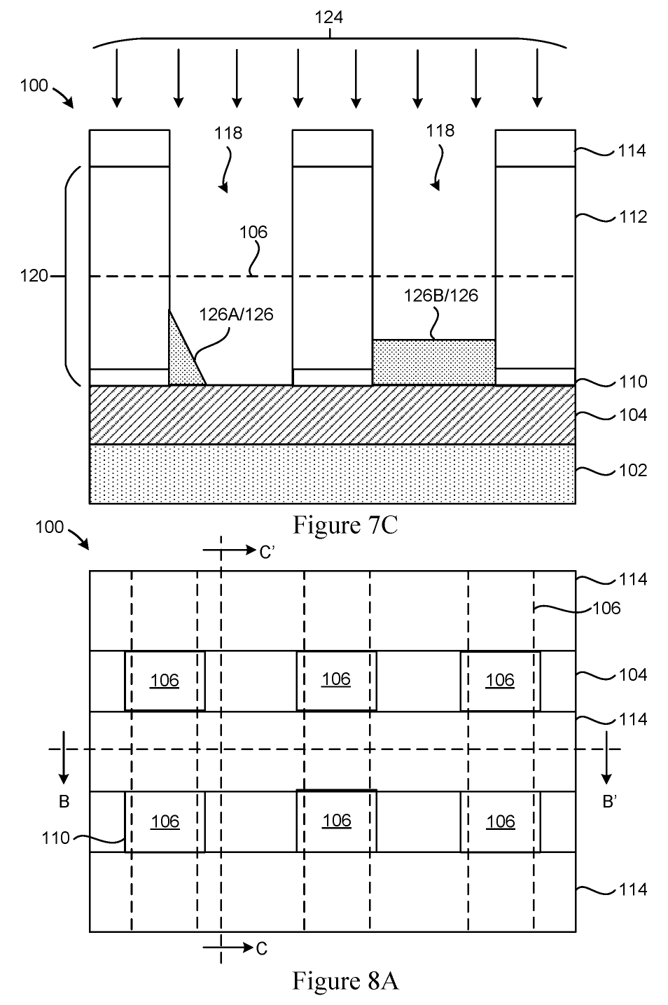

In FIGS. 7A, 7B, and 7C, a particle treatment 124 is performed on the residues 122 (including residues 122A and 122B) of FIGS. 6A and 6C remaining from the dummy gate patterning operation. The particle treatment 124 is performed on the semiconductor device 100 to modify the residues 122 (including residues 122A and 122B) and form modified residues 126 (including modified residues 126A and 126B). In some embodiments, the particle treatment 124 amorphizes the crystalline material of the residues 122 (including residues 122A and 122B). Accordingly, the modified residues 126 (including modified residues 126A and 126B) may be also referred to as amorphized residues. In an embodiment when the residues 122 (including residues 122A and 122B) comprise crystalline silicon, the modified residues 126 (including modified residues 126A and 126B) comprise amorphous silicon.

In an embodiment, the particle treatment 124 includes a gas cluster beam treatment that directs clusters of gas molecules toward the exposed surfaces of the semiconductor device 100. In another embodiment, the particle treatment 124 includes an ion beam treatment that directs energetic ions toward the exposed surfaces. In yet another embodiment, the particle treatment 124 includes a plasma treatment that generates ions within a plasma environment, which are then accelerated toward the substrate 102.

In some embodiments, the particle treatment 124 employs directional beams oriented substantially perpendicular (as indicated by arrows in FIG. 7C) to the major surface of the substrate 102. In various embodiments, the beams may be oriented at slight angles, such as one degree or two degrees from vertical, to enhance coverage of residues located at corners or along sidewalls. The beam angle can be controlled depending on the location and amount of the residues. The beam energy and ion species are selected based on the material composition of the residues and the desired depth of amorphization. In an embodiment, inert gas species such as argon, neon, or krypton are used to provide physical bombardment without introducing unwanted chemical reactions with the silicon material.

As shown in FIG. 7C, the dummy gate stacks 120 are protected from the particle treatment by the mask layer 114. The mask layer 114 shields the underlying polysilicon material of the dummy gate electrode layer 112 from the directional beams, preventing unwanted amorphization of the gate structures. The vertical or near-vertical orientation of the particle beams ensures that the mask layer 114 effectively blocks the beams from reaching the top surfaces of the dummy gate electrode layer 112. Similarly, as shown in FIG. 7A, the fins 106 are protected by the dielectric layer 110 positioned over the top surfaces and sidewalls of the fins 106. The dielectric layer 110 prevents the particle treatment 124 from amorphizing the crystalline silicon of the fins 106. This selective exposure enables the particle treatment 124 to target the residues 122 (including residues 122A and 122B) while preserving the crystalline structure of functional device elements.

Following the particle treatment 124, the modified residues 126 (including modified residues 126A and 126B) exhibit different chemical properties compared to crystalline silicon, particularly with respect to wet etch processes. The etch rate of amorphous silicon can be substantially greater than the etch rate of crystalline silicon when exposed to the same wet etch chemistry, providing a process window for complete residue removal without damaging functional device structures. This difference in etch rates enables selective removal of the modified residues 126 (including modified residues 126A and 126B) in subsequent processing steps while preserving the crystalline silicon of the dummy gate electrode layer 112 and fins 106.

In various embodiments, the particle treatment 124 can be performed using commercially available semiconductor processing equipment. Gas cluster beam treatment may be performed using tools configured to generate and accelerate clusters of gas molecules. Ion beam treatment may be performed using ion implantation tools or dedicated ion beam etching tools. Plasma treatment may be performed using reactive ion etching tools operated with inert gas chemistries and process conditions configured to generate directional ion bombardment.

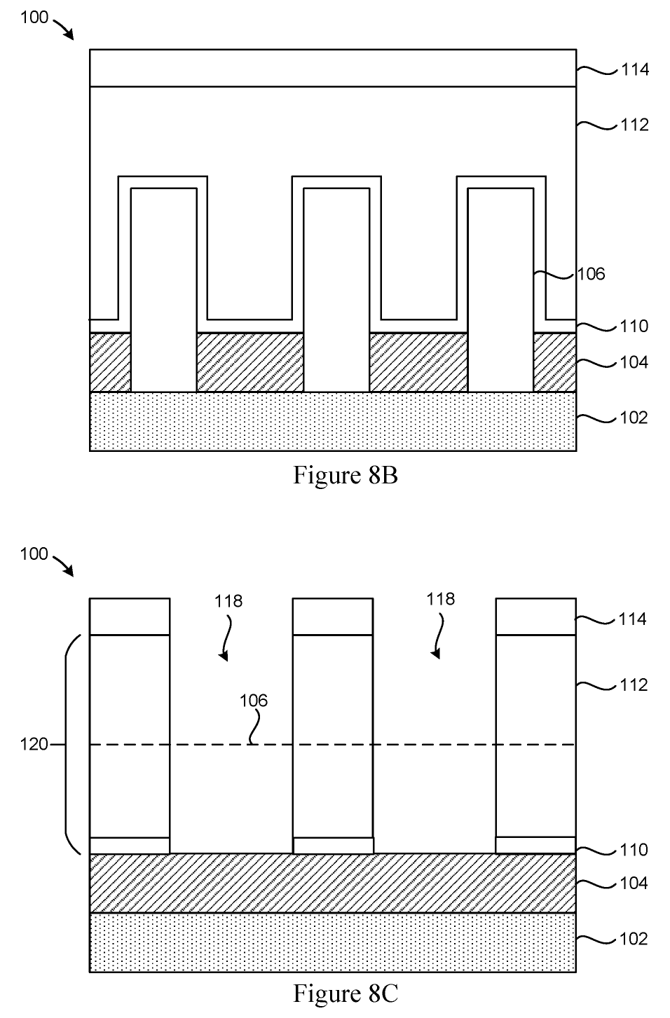

In FIGS. 8A, 8B, and 8C, the modified residues 126 (including modified residues 126A and 126B) of FIGS. 7A and 7C are removed from the trenches 118 between adjacent dummy gate stacks 120. The removal process exposes sidewalls of the dummy gate electrode layer 112 and sidewalls of the fins 106 within the trenches. In some embodiments, the removal process includes a wet etch process using an alkaline solution that selectively etches amorphous silicon at a higher rate than crystalline silicon. In an embodiment, the wet etch process may be performed using potassium hydroxide (KOH), sodium hydroxide (NaOH) solutions, or the like.

The selectivity of the wet etch process enables substantially complete removal of the modified residues 126 (including modified residues 126A and 126B) without significantly etching the crystalline silicon of the dummy gate electrode layer 112 and fins 106. The wet etch process parameters, including solution concentration, temperature, etch duration, may be selected to achieve complete removal of the amorphized residues while minimizing etching of crystalline silicon structures. The wet etch process may be performed in a wet etch tool configured for batch processing of semiconductor wafers or in a single-wafer wet processing tool.

The removal of the modified residues 126 (including modified residues 126A and 126B) of FIGS. 7A and 7C provides several advantages for the fabrication of the semiconductor device 100. The removal of residues along the sidewalls of the dummy gate stacks 120 prevents threshold voltage shifts and other performance variations that can result from variations in gate dimensions and geometry. The removal of residues along the sidewalls of the fins 106 prevents short circuits between adjacent transistor structures that can occur when residual material creates electrical connections between dummy gate stacks 120. The selective nature of the wet etch process enables substantially complete residue removal without requiring excessive over-etching during the initial dummy gate patterning process, thereby preserving the profile integrity of the dummy gate stacks 120.

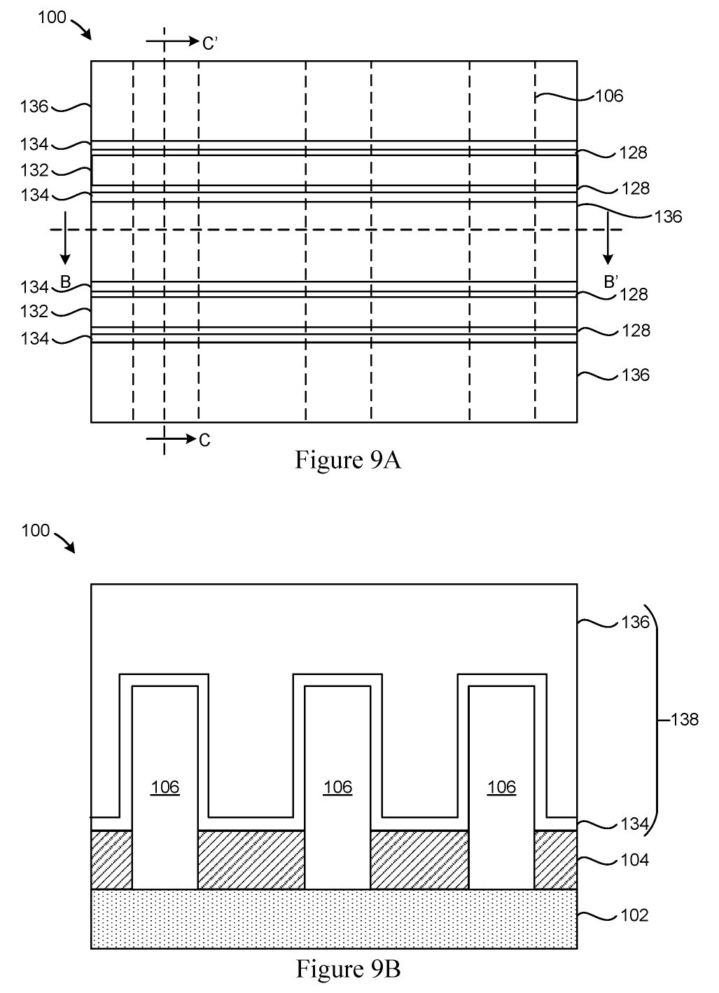

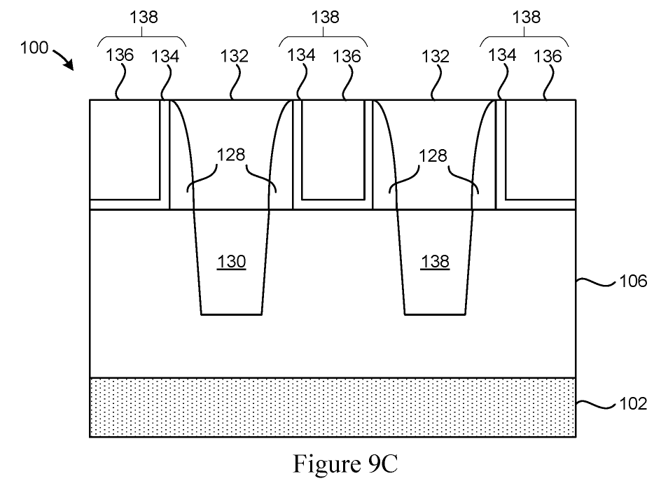

FIGS. 9A, 9B, and 9C illustrate a final stage in the formation of the semiconductor device 100, showing the completion of the device structure with spacers 128, epitaxial regions 130, dielectric layer 132, and replacement gates 138 (including gate dielectric layer 134 and gate electrode layer 136).

In some embodiments, the spacers 128 are formed adjacent to the sidewalls of the dummy gate stacks 120 (see FIGS. 8A-8C) and provide isolation between subsequently formed replacement gates 138 and epitaxial regions 130. In various embodiments, the spacers 128 may comprise silicon dioxide, silicon nitride, silicon oxynitride, a combination thereof, or the like.

The spacers 128 may be formed through a deposition and etch-back process where a dielectric layer is blanket deposited over the entire structure using CVD, LPCVD, PECVD, ALD, a combination thereof, or the like, followed by anisotropic etching to remove the dielectric material from horizontal surfaces while leaving material on the vertical sidewalls of the dummy gate stacks 120 (see FIGS. 8A-8C). In an embodiment, the spacers 128 may comprise multiple layers with different materials to optimize electrical isolation, mechanical stress, and/or etch selectivity characteristics.

In some embodiments, the epitaxial regions 130 are formed in the exposed portions of the fins 106 that are not covered by the dummy gate stacks 120 (see FIGS. 8A-8C) or spacers 128. The epitaxial regions 130 serve as source and drain regions for the transistor devices. In various embodiments, the epitaxial regions 130 may comprise silicon, germanium, silicon- germanium alloys, silicon-carbon alloys, III-V compound semiconductors, or the like, and may be grown using selective epitaxial growth techniques. The epitaxial regions 130 may be doped during the growth using precursors such as diborane (B₂H₆) for p-type doping or phosphine (PH₃) for n-type doping, for example. In some embodiments, the epitaxial regions 130 may be doped after the epitaxial growth using an ion implantation of suitable dopants.

The dielectric layer 132 is formed over the epitaxial regions 130 and spacers 128 to provide electrical isolation. In various embodiments, the dielectric layer 132 comprises silicon dioxide, low-k dielectric materials such as fluorinated silicon dioxide, carbon-doped silicon dioxide, a combination thereof, or the like, and may be formed using CVD, LPCVD, PECVD, ALD, spin-on deposition, a combination thereof, or the like.

The formation of the replacement gates 138 comprises removing the dummy gate stacks 120 (see FIG. 8A-8C) and forming functional gate structures comprising the gate dielectric layer 134 and gate electrode layer 136. The dummy gate removal is accomplished through selective etching processes that remove the material of the dummy gate stacks 120 while preserving the surrounding spacers 128 and dielectric layer 132. In various embodiments, the selective etching employs wet chemical etching using solutions such as tetramethylammonium hydroxide (TMAH) or ammonium hydroxide, or dry plasma etching using fluorine-based chemistries that provide high selectivity between polysilicon and the surrounding materials.

The gate dielectric layer 134 is formed in the openings created by dummy gate removal and provides the insulating layer between the gate electrode and the channel regions of the fins 106. In various embodiments, the gate dielectric layer 134 comprises high-k dielectric materials such as hafnium oxide, hafnium silicon oxide, hafnium aluminum oxide, zirconium oxide, or the like, and may be formed using CVD, LPCVD, PECVD, ALD, a combination thereof, or the like.

The gate electrode layer 136 is formed over the gate dielectric layer 134 to complete the replacement gate structure. In various embodiments, the gate electrode layer 136 comprises a metal gate stack including work function metals and fill metals to achieve the desired threshold voltage and electrical performance. For p-type devices, the work function metal may comprise titanium nitride, tantalum nitride, or tungsten, while for n-type devices, the work function metal may comprise titanium aluminum, tantalum aluminum carbide, or lanthanum-containing materials. The gate electrode layer 136 is completed with a fill metal such as tungsten, aluminum, copper, or the like, deposited using CVD, physical vapor deposition (PVD), a combination thereof, or the like to fill the gate opening.

In some embodiments, a planarization process may be performed to remove excess materials of the replacement gates 138 extending over the top surface of the dielectric layer 132 and to expose the top surface of the dielectric layer 132. The planarization process may comprise etching, CMP, a combination thereof, or the like. After the planarization process, top surfaces of the replacement gates 138 are substantially level or co-planar with the top surface of the dielectric layer 132 within process variations of the planarization process.

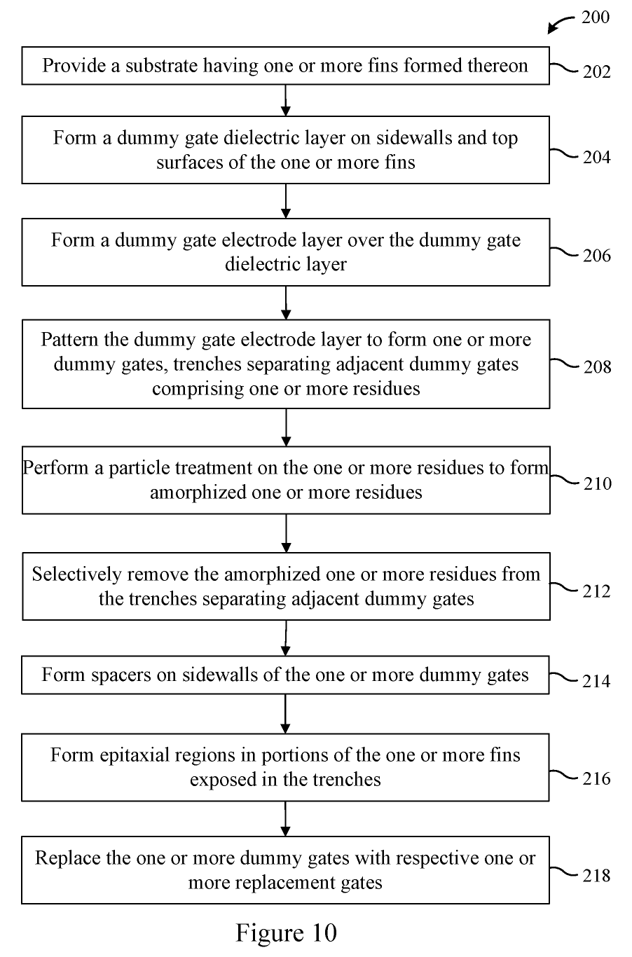

FIG. 10 illustrates a flow diagram of a method 200 for controlling a dummy gate profile, in accordance with various embodiments. Although shown in a particular sequence, it should be appreciated that the steps of the method 200 may be performed in any suitable sequence. Furthermore, one or more of the steps of the method 200 may be omitted.

The method 200 starts with step 202 when a substrate (e.g., substrate 102 of FIG. 1B) is provided. In some embodiments, the substrate comprises one or more fins (e.g., fins 106 of FIGS. 1A and 1B) formed thereon, as described in FIGS. 1A and 1B. In step 204, a dummy gate dielectric layer (e.g., dielectric layer 110 of FIGS. 2A and 2B) is formed on sidewalls and top surfaces of the one or more fins, as described in FIGS. 2A and 2B. In step 206, a dummy gate electrode layer (e.g., dummy gate electrode layer 112 of FIGS. 2A and 2B) is formed over the dummy gate dielectric layer, as described in FIGS. 3A and 3B.

In step 208, the dummy gate electrode layer is patterned to form one or more dummy gates (e.g., dummy gates 120 of FIG. 6C), as described in FIGS. 4A, 4B, 5A, 5B, 5C, 6A, 6B, and 6C. In some embodiments, trenches (e.g., trenches 118 of FIG. 6C) separating adjacent dummy gates comprise one or more residues (e.g., residues 122 of FIGS. 6A and 6C). In step 210, a particle treatment (e.g., particle treatment 124 of FIG. 7C) is performed on the one or more residues to form amorphized one or more residues (e.g., modified residues 126 of FIGS. 7A and 7C), as described in FIGS. 7A, 7B, and 7C. In step 212, the amorphized one or more residues are selectively removed from the trenches separating adjacent dummy gates, as described in FIGS. 8A, 8B, and 8C.

In step 214, spacers (e.g., spacers 128 of FIGS. 9A and 9C) are formed on sidewalls of the one or more dummy gates, as described in FIGS. 9A, 9B, and 9C. In step 216, epitaxial regions (e.g., epitaxial regions 130 of FIG. 9C) are formed in portions of the one or more fins exposed in the trenches, as described in FIGS. 9A, 9B, and 9C. In step 218, the one or more dummy gates are replaced with respective one or more replacement gates (e.g., replacement gates 138 of FIG. 9C), as described in FIGS. 9A, 9B, and 9C.

Example embodiments of the disclosure are described below. Other embodiments can also be understood from the entirety of the specification as well as the claims filed herein.

Example 1. A method including: providing a substrate having a fin formed thereon; forming a dummy gate dielectric layer along sidewalls and a top surface of the fin; forming a dummy gate electrode layer over the dummy gate dielectric layer; patterning the dummy gate electrode layer to form a dummy gate, a sidewall of the dummy gate including a first residue; amorphizing the first residue to form an amorphized first residue; and selectively removing the amorphized first residue.

Example 2. The method of Example 1, where amorphizing the first residue includes performing a particle treatment on the first residue.

Example 3. The method of Example 2, where the particle treatment includes a gas cluster beam treatment, an ion beam treatment, or a plasma treatment.

Example 4. The method of any of Examples 1 to 3, where selectively removing the amorphized first residue includes performing a wet etch process on the amorphized first residue.

Example 5. The method of Example 4, where an etch rate of the amorphized first residue is greater than an etch rate of the first residue while performing the wet etch process.

Example 6. The method of any of Examples 1 to 5, where, after patterning the dummy gate electrode layer, a sidewall of the fin includes a second residue.

Example 7. The method of Example 6, further including: amorphizing the second residue to form an amorphized second residue; and selectively removing the amorphized second residue.

Example 8. A method including: providing a substrate having a fin extending from a major surface of the substrate; forming a dummy gate dielectric layer along sidewalls and a top surface of the fin; forming a dummy gate electrode layer over the dummy gate dielectric layer; patterning the dummy gate electrode layer to form one or more trenches in the dummy gate electrode layer, where the one or more trenches include one or more residues; performing a particle treatment on the one or more residues to form amorphized one or more residues; and selectively removing the amorphized one or more residues.

Example 9. The method of Example 8, where the one or more residues include crystalline silicon and the amorphized one or more residues include amorphous silicon.

Example 10. The method of any of Examples 8 and 9, where the one or more residues extend along one or more sidewalls of the fin exposed within the one or more trenches.

Example 11. The method of any of Examples 8 to 10, where the one or more residues extend along sidewalls of the one or more trenches.

Example 12. The method of any of Examples 8 to 11, where selectively removing the amorphized one or more residues includes performing a wet etch process on the amorphized one or more residues.

Example 13. The method of Example 12, where the wet etch process is performed using KOH or NaOH.

Example 14. The method of any of Examples 8 to 13, where the particle treatment includes a gas cluster beam treatment, an ion beam treatment, or a plasma treatment.

Example 15. A method including: providing a substrate having a fin formed thereon; depositing a dielectric layer along sidewalls and a top surface of the fin; depositing a polysilicon layer over the dielectric layer; etching the polysilicon layer to form a dummy gate, a sidewall of the dummy gate including a first residue and a sidewall of the fin including a second residue; performing a particle treatment on the first residue and the second residue to form a modified first residue and a modified second residue, where the modified first residue and the modified second residue include amorphous silicon; and selectively etching the modified first residue and the modified second residue.

Example 16. The method of Example 15, where the particle treatment includes a gas cluster beam treatment, an ion beam treatment, or a plasma treatment.

Example 17. The method of any of Examples 15 and 16, where selectively etching the modified first residue and the modified second residue includes performing a wet etch process.

Example 18. The method of Example 17, where an etch rate of the amorphous silicon is greater than an etch rate of crystalline silicon while performing the wet etch process.

Example 19. The method of any of Examples 17 and 18, where the wet etch process is performed using KOH or NaOH.

Example 20. The method of any of Examples 15 to 19, further including replacing the dummy gate with a replacement gate.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present disclosure can be embodied and viewed in many different ways.

“Substrate,” “target substrate,” “structure,” or “device” as used herein generically refers to an object being processed in accordance with the disclosure, and may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate, structure, or device is not limited to any particular base structure, underlying layer or overlying layer, patterned or un-patterned, but rather, is contemplated to include any such layer or base structure, and any combination of layers and/or base structures. The description may reference particular types of substrates, structures, or devices, but this is for illustrative purposes only.

Although this disclosure describes particular process steps as occurring in a particular order, this disclosure contemplates the process steps occurring in any suitable order. While this disclosure has been described with reference to illustrative embodiments, this description is not intended to be construed in a limiting sense. Various modifications and combinations of the illustrative embodiments, as well as other embodiments of the disclosure, will be apparent to persons skilled in the art upon reference to the description. It is therefore intended that the appended claims encompass any such modifications or embodiments.

What is claimed is:

1. A method comprising:
providing a substrate having a fin formed thereon;
forming a dummy gate dielectric layer along sidewalls and a top surface of the fin;
forming a dummy gate electrode layer over the dummy gate dielectric layer;
patterning the dummy gate electrode layer to form a dummy gate, a sidewall of the dummy gate comprising a first residue;
amorphizing the first residue to form an amorphized first residue; and
selectively removing the amorphized first residue.

2. The method of claim 1, wherein amorphizing the first residue comprises performing a particle treatment on the first residue.

3. The method of claim 2, wherein the particle treatment comprises a gas cluster beam treatment, an ion beam treatment, or a plasma treatment.

4. The method of claim 1, wherein selectively removing the amorphized first residue comprises performing a wet etch process on the amorphized first residue.

5. The method of claim 4, wherein an etch rate of the amorphized first residue is greater than an etch rate of the first residue while performing the wet etch process.

6. The method of claim 1, wherein, after patterning the dummy gate electrode layer, a sidewall of the fin comprises a second residue.

7. The method of claim 6, further comprising:
amorphizing the second residue to form an amorphized second residue; and
selectively removing the amorphized second residue.

8. A method comprising:
providing a substrate having a fin extending from a major surface of the substrate;
forming a dummy gate dielectric layer along sidewalls and a top surface of the fin;
forming a dummy gate electrode layer over the dummy gate dielectric layer;
patterning the dummy gate electrode layer to form one or more trenches in the dummy gate electrode layer, wherein the one or more trenches comprise one or more residues;
performing a particle treatment on the one or more residues to form amorphized one or more residues; and
selectively removing the amorphized one or more residues.

9. The method of claim 8, wherein the one or more residues comprise crystalline silicon and the amorphized one or more residues comprise amorphous silicon.

10. The method of claim 8, wherein the one or more residues extend along one or more sidewalls of the fin exposed within the one or more trenches.

11. The method of claim 8, wherein the one or more residues extend along sidewalls of the one or more trenches.

12. The method of claim 8, wherein selectively removing the amorphized one or more residues comprises performing a wet etch process on the amorphized one or more residues.

13. The method of claim 12, wherein the wet etch process is performed using KOH or NaOH.

14. The method of claim 8, wherein the particle treatment comprises a gas cluster beam treatment, an ion beam treatment, or a plasma treatment.

15. A method comprising:
providing a substrate having a fin formed thereon;
depositing a dielectric layer along sidewalls and a top surface of the fin;
depositing a polysilicon layer over the dielectric layer;
etching the polysilicon layer to form a dummy gate, a sidewall of the dummy gate comprising a first residue and a sidewall of the fin comprising a second residue;
performing a particle treatment on the first residue and the second residue to form a modified first residue and a modified second residue, wherein the modified first residue and the modified second residue comprise amorphous silicon; and
selectively etching the modified first residue and the modified second residue.

16. The method of claim 15, wherein the particle treatment comprises a gas cluster beam treatment, an ion beam treatment, or a plasma treatment.

17. The method of claim 15, wherein selectively etching the modified first residue and the modified second residue comprises performing a wet etch process.

18. The method of claim 17, wherein an etch rate of the amorphous silicon is greater than an etch rate of crystalline silicon while performing the wet etch process.

19. The method of claim 17, wherein the wet etch process is performed using KOH or NaOH.

20. The method of claim 15, further comprising replacing the dummy gate with a replacement gate.
